(19) United States
(12) Patent Application Publication
(10) Pub. No.: US 2010/0166224 A1
(43) Pub. Date: Jul. 1, 2010

(54) LOUDNESS CIRCUIT WITHOUT OPERATIONAL AMPLIFIER

(75) Inventors: Li-Ying CHANG, Taipei County 220 (TW); Yeh-Wu CHUNG, Taipei County 231 (TW)

Correspondence Address: Muncy, Geissler, Olds & Lowe, PLLC, 4000 Legato Road, Suite 310, FAIRFAX, VA, 22033, US

(73) Assignee: PRINCETON TECHNOLOGY CORPORATION, HsinTien, (TW)

(21) Appl. No.: 12/619,115

(22) Filed: Nov. 16, 2009

(30) Foreign Application Priority Data
Dec. 31, 2008 (TW) 097151745

(51) Int. Cl. H03G 3/00

(52) U.S. Cl. 381/107

(57) ABSTRACT

A loudness circuit without operational amplifiers is provided. The loudness circuit includes a first equivalent resistance circuit for accepting an audio signal; a second equivalent resistance circuit connected to the first equivalent resistance circuit; and a series resistor and capacitor, parallel connected with the second equivalent resistance circuit for determining zeros of the loudness circuit; wherein the first and the second equivalent resistance circuit, the resistor and the capacitor regulates the output gain of the loudness circuit in all frequency bands such that the gain is raised in a predetermined low-frequency band and reduced in a predetermined high-frequency band, and a loudness signal is output from the second equivalent resistance circuit such that zeros of the loudness circuit are fixed.

### CROSS REFERENCE TO RELATED APPLICATION

This Application claims priority of Taiwan Patent Application No. 97151745, filed on Dec. 31, 2008, the entirety of which is incorporated by reference herein.

### FIELD OF THE INVENTION

The present invention relates to a loudness circuit, and in particular relates to a loudness circuit without operational amplifiers.

### DESCRIPTION OF THE RELATED ART

Typically, the characteristics of loudness circuits are that they output a apparently raised voltage gain in the range from a specified low-frequency band to a specified high-frequency band. The conventional loudness circuit 100 as shown in FIG. 1A shows, is a circuit including passive elements R1, R2, Rout, C and an operational amplifier A and an addition circuit S. The operational amplifier A is a buffer, and the RC circuit is used to regulate the signal frequency responses at each node. The output frequency response is obtained by coupling node signals through the adder S. As FIG. 1B shows, the output frequency response of the loudness circuit 100 has the characteristic wherein the output gain is higher in low-frequency bands and output gain is lower in high-frequency bands. Additionally, zeros and poles of transfer functions are also held stable. Referring to U.S. Pat. No. 5,325,440, titled “loudness control circuit”, low pass filter circuits comprise several passive elements and operational amplifiers. The operational amplifiers are used for amplifying, attenuating, isolating or buffering etc. While, integrating the operational amplifiers with other passive elements in a chip, allow designers to more flexibly adjust system frequency response. However, the increased operational amplifiers increase chip area, draw much current and cause noise distortion etc.

Thus, a loudness circuit mitigating the disadvantages of employing operational amplifiers while maintaining predetermined frequency responses is required.

### BRIEF SUMMARY OF INVENTION

A detailed description is given in the following embodiments with reference to the accompanying drawings.

In one aspect, the present invention provides a loudness circuit without operational amplifiers. The loudness circuit includes a first equivalent resistance circuit for accepting an audio signal; a second equivalent resistance circuit connected to the first equivalent resistance circuit; and a series resistor and capacitor, parallel connected with the second equivalent resistance circuit for determining zeros of the loudness circuit; wherein the first and the second equivalent resistance circuit, the resistor and the capacitor regulates the output gain of the loudness circuit in all frequency bands such that the gain is raised in a predetermined low-frequency band and reduced in a predetermined high-frequency band, and a loudness signal is output from the second equivalent resistance circuit such that zeros of the loudness circuit are fixed.

The abovementioned loudness circuit exclude from utilizing any operational amplifier to enormously reduce noise interference, consumed current and chip area.

### BRIEF DESCRIPTION OF DRAWINGS

The present invention can be more fully understood by reading the subsequent detailed description and examples with references made to the accompanying drawings, wherein:

FIG. 1A is a equivalent schematic diagram showing a conventional loudness circuit;

FIG. 1B is a frequency response diagram showing loudness circuit of FIG. 1A;

FIG. 2A is a schematic diagram showing the loudness circuit according to an embodiment of the present invention;

FIG. 2B is a equivalent schematic diagram showing the loudness circuit of FIG. 2A according to an embodiment of the present invention;

FIG. 2C is a frequency response diagram showing the loudness circuit of FIG. 2A;

FIG. 3A is a equivalent schematic diagram showing the loudness circuit according to another embodiment of the present invention;

FIG. 3B is a frequency response diagram showing several loudness circuits according to an embodiment of the present invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

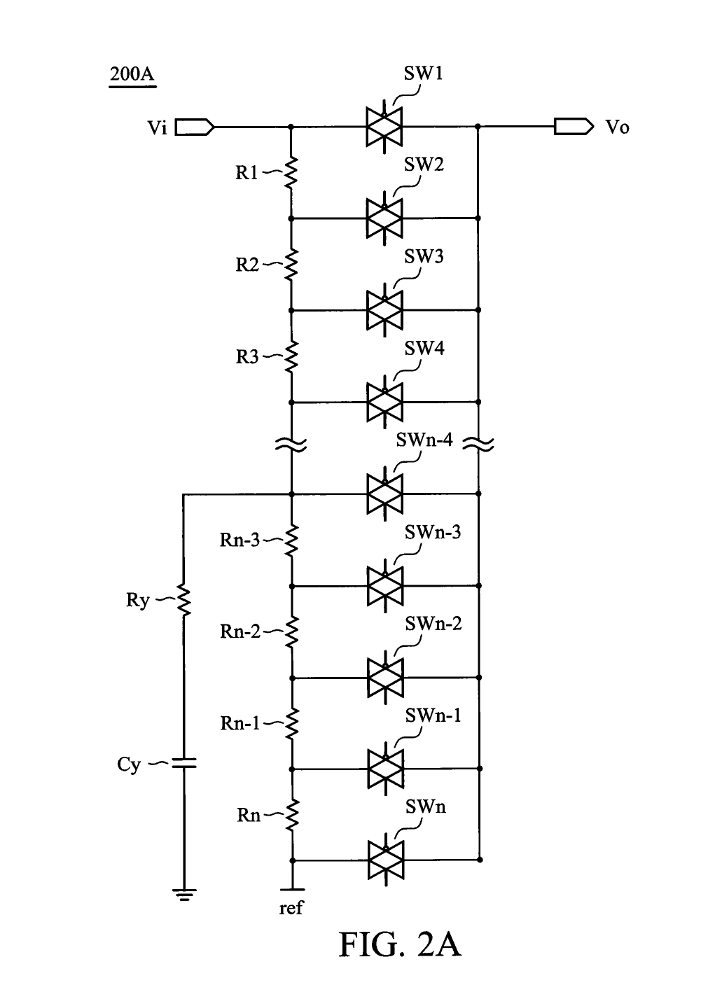

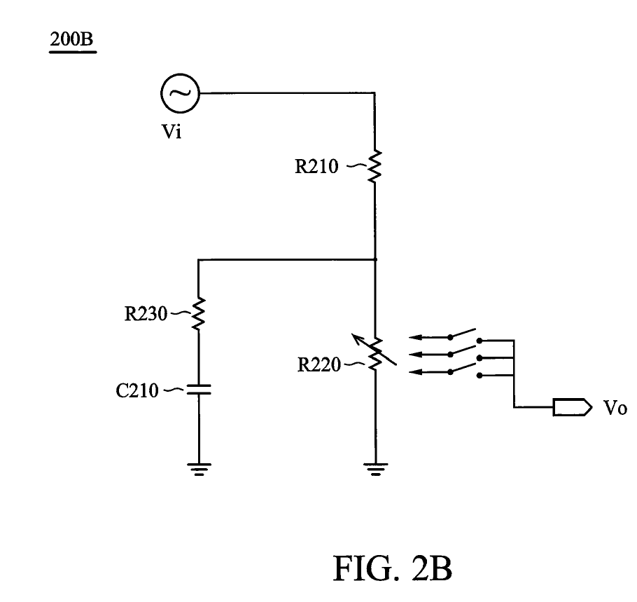

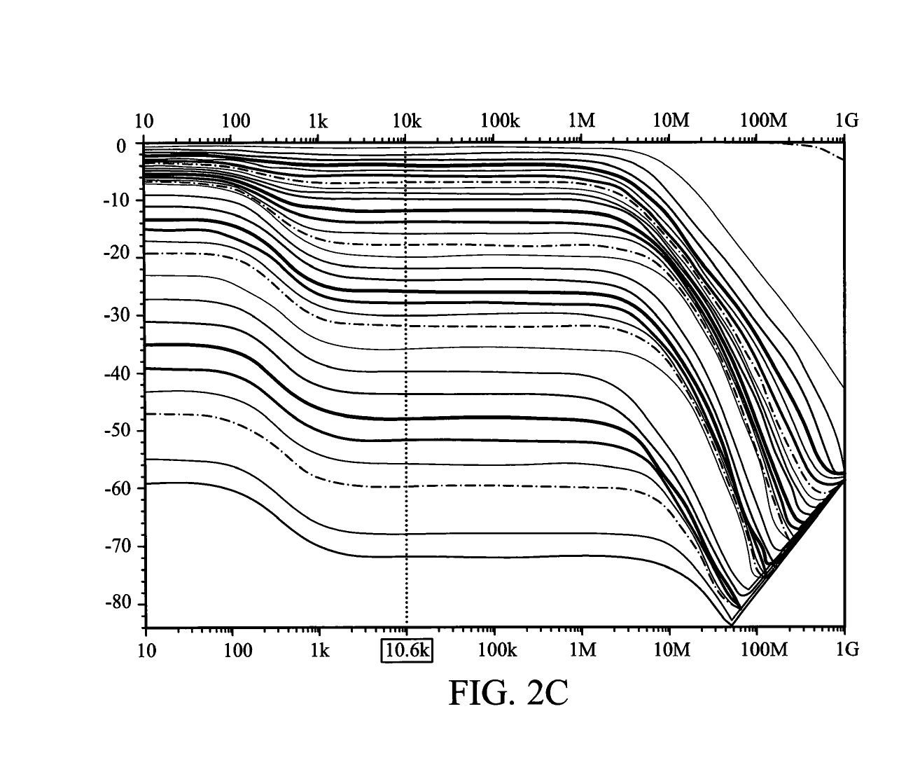

FIG. 2A is a schematic diagram showing the loudness circuit according to the embodiment of the present invention. The loudness circuit includes resistors R1, R2 . . . Rn, Ry and Cy, and a plurality of switches SW1 . . . SWn. The input signal Vi is connected to one terminal of resistor R1 and switch SW1, the signal is output at the other terminals of the switches SW1 . . . SWn. The serialized resistor Ry and the capacitor Cy is alternatively connected to one terminal of resistor R1 . . . Rn according to the embodiment of the present invention. The output combination can be regulated through the switches. FIG. 2B is an equivalent schematic diagram showing the loudness circuit 200A of FIG. 2A. In the embodiment, the resistances of resistor R210 and R220 are determined firstly, and then the serialized Ry and Cy is connected such that an upper portion resistance circuit and a lower portion resistance circuit are built up. The upper equivalent resistance is equivalent to the resistor R210 and the lower equivalent resistance is equivalent to the resistor R220 in FIG. 2B. The output terminal can be changed arbitrarily by conducting other switches to output different loudness signal. The resistor Ry and capacitor Cy in FIG. 2A are respectively equivalent to the resistor R230 and the capacitor C210 in FIG. 2B.

When the output signal Vo is output from the terminal of the second equivalent resistor R220, the output frequency response matches the characteristic of the loudness circuit with operation amplifiers. That is, to selectively conduct one of the switches SWn-3 to SWn to regulate output signal. To conduct the switch SWn-3 is preferred in the embodiment of the present invention.

After simplification, the circuit in FIG. 2A is converted to an equivalent circuit 200B in FIG. 2B. In accordance with well known circuit principals, the transfer function of output voltage signal Vo to input voltage signal Vi can be expressed as:

$$\frac{Vo ( s )}{Vi ( s )} = \frac{\begin{matrix}( \frac{R 220 \times R 230}{R 210 \times R 220 + R 220 \times R 230 + R 210 \times R 230} ) s + \\ ( \frac{R 220}{C 210 ( R 210 \times R 220 + R 220 \times R 230 + R 210 \times R 230 )} )\end{matrix}}{s + ( \frac{R 210 + R 220}{C 210 ( R 210 \times R 220 \times R 230 + R 210 \times R 230 )} )}$$

where zeros of the circuit are at

$$s = \frac{1}{C 210 \times R 230} ,$$

poles of the circuit are at

$$s = \frac{R 210 + R 220}{C 210 ( R 210 \times R 220 + R 220 \times R 230 + R 210 \times R 230 )} ,$$

The voltage gain in high-frequency

$${A}_{V} = \frac{R 220}{( R 210 + R 220 )} .$$

and the voltage gain in low-frequency

$${A}_{V} = \frac{R 220 // R 230}{( R 210 + R 220 // R 230 )} ,$$

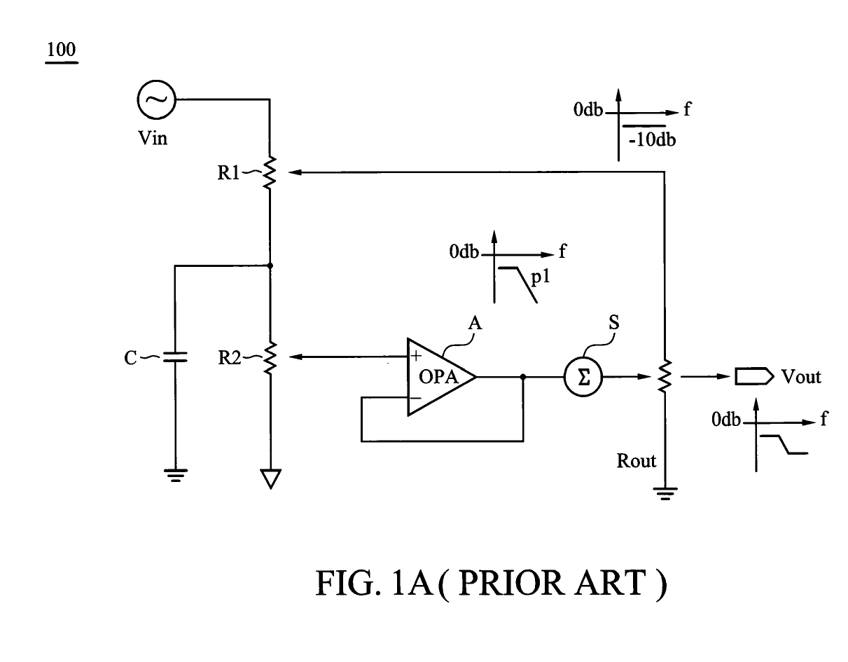

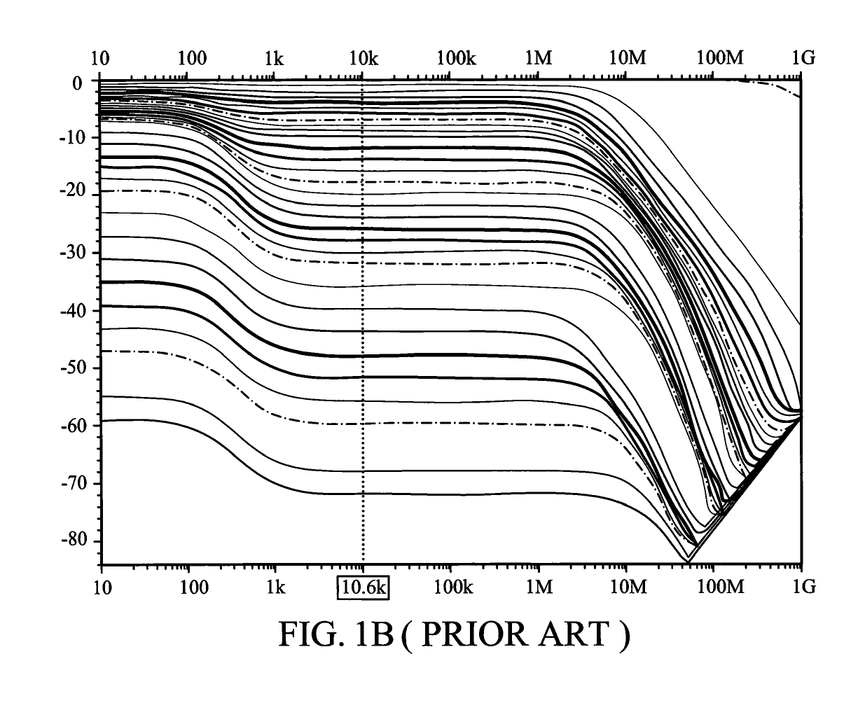

Noted that the capacitor C210 and the resistor R230 determine zeros of the loudness circuit, and to fix capacitor C210 and resistor R230 can fix zeros of the circuit. In the embodiment of the present invention, resistor R210 is predetermined and fixed to calculate frequency responses which are similar to the loudness circuit with operational amplifiers of FIG. 1B. For output Vo, the resistor R220 is variable by switching switches, however, for the overall circuit the resistor R220 is fixed. Thus, poles of the loudness circuit 200B will be steady because resistor R230, R220, capacitor C210 and resistor R210 are fixed. Therefore, zeros and poles of the loudness circuit 200B are stable in the present invention.

The DC gain and the low-frequency gain e.g. below 100Hz can be raised by raising the resistor R220 (i.e. to open or close switches for regulation). The high-frequency gain e.g. 1KHz to 10MHz is originally lower than the low-frequency gain. Even though resistor R220 is changed, the gain (Av) in high-frequency is still much smaller than the gain (Av) in low-frequency. The feature of the present invention in FIG. 2B is similar to that of the loudness circuit with operational amplifiers in FIG. 1A, as the frequency response diagram shows in FIG. 2C. It is noted that the gain difference in high-frequency and low-frequency is identical (ex: Av=3 in low frequency and Av=1 in high frequency, when the R220 is changed, the Av=6 in low frequency and Av=2 in high frequency). From the view point of db value (db=20log(Av)), the db variation amplitude between high frequency and low frequency is identical (i.e. db value difference is unchanged). Comparing frequency responses of FIG. 1B with those of FIG. 2C, the curves shown in FIG. 2C are regulated by the resistor R220 of FIG. 2B. The gain characteristics in low-frequency and high -frequency shown in FIG. 1B and FIG. 2C are identical.

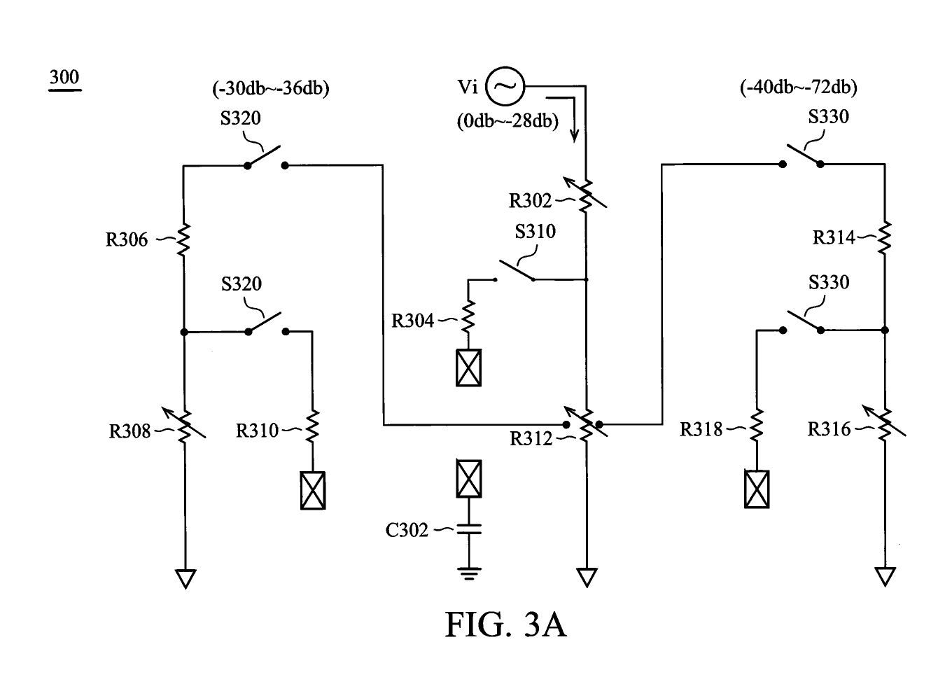

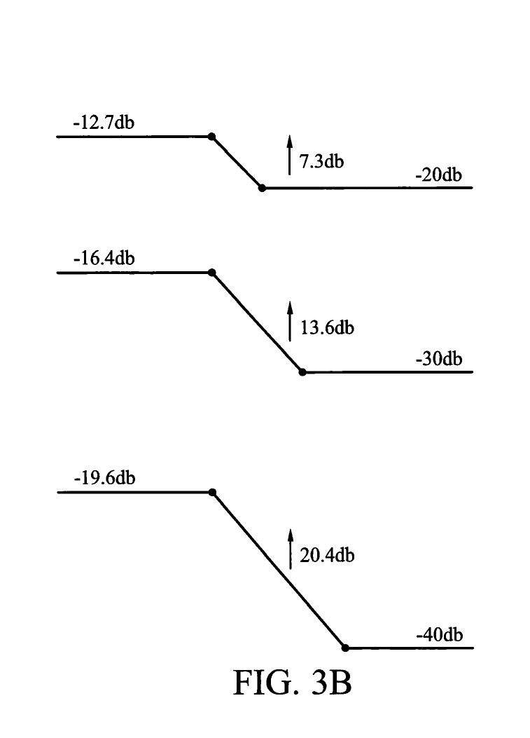

FIG. 3A is an equivalent schematic diagram showing the loudness circuit according to another embodiment of the present invention. A loudness circuit without operational amplifiers is connected to other loudness circuits without operational amplifiers. The connection decreases gain difference between low-frequency and high-frequency, namely gain attenuation in high-frequency is intensified. FIG. 3B is a frequency response diagram showing several loudness circuits according to an embodiment of the present invention. FIG. 3B also illustrates respective frequency responses of loudness circuits in FIG. 3A. A loudness circuit is connected to a specified loudness circuit through a switch for reaching a different frequency response. When the switch S310 in FIG. 3A is closed, the frequency response is displayed as the top diagram in the FIG. 3B. When the switch S320 in FIG. 3A is closed, the frequency response is displayed as the middle diagram in the FIG. 3B. When the switch S330 in FIG. 3A is closed the frequency response is displayed as the down diagram in the FIG. 3B. With regard to the frequency responses of FIG. 3B, in the embodiment of the present invention, the gain difference between the high-frequency and the low-frequency is 7.3 db when the switch S310 is closed. The gain difference between high-frequency and low-frequency is 13.6 db when the switch S320 is closed. The gain difference between high-frequency and low-frequency is 20.4 db when the switch S330 is closed. With regard to the loudness circuit 200B of FIG. 2B, the gain difference between the high-frequency and the low-frequency is fixed, and the loudness circuit 300 of FIG. 3A has more flexibility, is available to regulate gain difference between the high-frequency and the low-frequency.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A loudness circuit without operational amplifiers, comprising:
a first equivalent resistance circuit for accepting an audio signal;
a second equivalent resistance circuit connected to the first equivalent resistance circuit; and
a series circuit with a first resistor and a first capacitor for parallel connection with the second equivalent resistance circuit to determine zero points of the loudness circuit;
wherein the first and the second equivalent resistance circuit, the resistor and the capacitor regulates the output gain of the loudness circuit in all frequency bands such that the gain is raised in a predetermined low-frequency band and reduced in a predetermined high-frequency band, and a loudness signal is output from the second equivalent resistance circuit such that said zero points of the loudness circuit are fixed.

2. The loudness circuit without operational amplifiers as claimed in claim 1, wherein the first and the second equivalent resistance circuits are made up of a plurality of series resistors.

3. The loudness circuit without operational amplifiers as claimed in claim 2, further comprising a plurality of switches connecting to the plurality of resistors for changing the loudness signal by switching the switches to regulate magnitude of output equivalent resistance.

4. The loudness circuit without operational amplifiers as claimed in claim 1, wherein the loudness circuit without operational amplifiers alternatively in parallel connects one or a plurality of loudness circuits without operational amplifiers to increase differences between the predetermined low-frequency gain and the predetermined high-frequency gain.
